(19) United States
(12) Patent Application Publication
(10) Pub. No.: US 2024/0310724 A1
(43) Pub. Date: Sep. 19, 2024

(54) PHOTORESIST COMPOSITION AND METHOD OF MANUFACTURING INTEGRATED CIRCUIT DEVICE USING THE SAME

(71) Applicant: Samsung Electronics Co., Ltd., Suwon-si (KR)

(72) Inventors: Honggu IM, Suwon-si (KR); Jaeyeon KIM, Suwon-si (KR); Juyoung KIM, Suwon-si (KR); Jicheol PARK, Suwon-si (KR); Yechan KIM, Suwon-si (KR); Yonghoon MOON, Suwon-si (KR)

(73) Assignee: Samsung Electronics Co., Ltd., Suwon-si (KR)

(21) Appl. No.: 18/589,918

(22) Filed: Feb. 28, 2024

(30) Foreign Application Priority Data
Mar. 14, 2023 (KR) 10-2023-0033468

(51) Int. Cl. G03F 7/004; G03F 7/00

(52) U.S. Cl. CPC G03F 7/0045; G03F 7/70033

(57) ABSTRACT

Provided is a photoresist composition including a chemically amplified polymer, a photoacid generator, a photo-decomposable quencher including a pyridinium-based material that generates a neutral material by exposure and acts as a base to neutralize an acid before exposure, and a solvent.

### CROSS-REFERENCE TO RELATED APPLICATION

This application is based on and claims priority under 35 U.S.C. § 119 to Korean Patent Application No. 10-2023-0033468, filed on Mar. 14, 2023 in the Korean Intellectual Property Office, the disclosure of which is incorporated by reference herein in its entirety.

### BACKGROUND

Inventive concepts relate to a photoresist composition and/or a method of manufacturing an integrated circuit device using the photoresist composition, and more particularly, to a photoresist composition for extreme ultraviolet (EUV) and/or a method of manufacturing an integrated circuit device using the photoresist composition.

Due to the development of electronic technology, down-scaling of semiconductor devices is rapidly progressing. Accordingly, a photolithography process for implementing fine patterns may be required. In particular, in a photolithography process for manufacturing integrated circuit devices, it may be necessary to a develop a technique that may increase the efficiency of the developing process as well as improve the dissolution contrast for a developing solution between exposed and unexposed areas of a photoresist film.

### SUMMARY

Inventive concepts provide a photoresist composition including a photo-decomposable quencher including a pyridinium-based material that generates a neutral material by exposure and acts as a base to neutralize an acid before exposure.

According to an example embodiment of inventive concepts, a photoresist composition may include a chemically amplified polymer, a photoacid generator, a photo-decomposable quencher including a pyridinium-based material that generates a neutral material by exposure and acts as a base to neutralize an acid before exposure, and a solvent.

According to an example embodiment of inventive concepts, a photo-decomposable quencher may include a pyridinium-based material that generates a neutral material by exposure and acts as a base to neutralize an acid before exposure. The pyridinium-based material may be represented by one of Chemical Formulae 1, 1-1, 2, 2-1, 3, and 3-1 below:

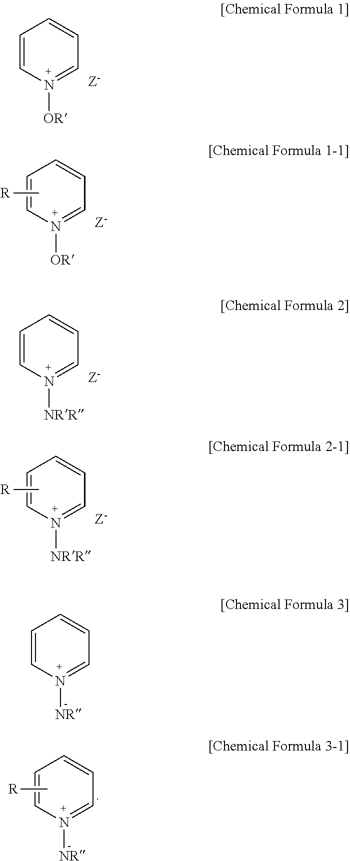

In Chemical Formulas 1, 1-1, 2, 2-1, 3, and 3-1, Z⁻ may be a counter ion; R may be hydrogen, a halogen element, or a substituted or unsubstituted alkyl group; R′ may be a methyl group; and R″ may be a tosyl group.

According to an example embodiment of inventive concepts, a method of manufacturing an integrated circuit device may include forming a photoresist film on a lower film by using a photoresist composition, the photoresist film including a chemically amplified polymer, a photoacid generator, and a photo-decomposable quencher, the photo-decomposable quencher including a pyridinium-based material that generates a neutral material by exposure and acts as a base to neutralize an acid before exposure; exposing a first area of the photoresist film to provide an exposed first area of the photoresist film, the exposing the first area of the photoresist film generating an acid in the first area, the acid being derived from the photoacid generator; deprotecting an acid-labile group included in the chemically amplified polymer using the acid in the exposed first area of the photoresist film; forming a photoresist pattern by removing the exposed first area of the photoresist film using a developing solution, the photoresist pattern including an unexposed area of the photoresist film; and processing the lower film using the photoresist pattern as a mask.

### BRIEF DESCRIPTION OF THE DRAWINGS

Embodiments will be more clearly understood from the following detailed description taken in conjunction with the accompanying drawings in which:

FIG. 1 is a flowchart illustrating a method of manufacturing an integrated circuit device according to an embodiment; and

FIGS. 2A to 2E are cross-sectional views sequentially illustrating in sequence a method of manufacturing an integrated circuit device, according to an embodiment.

### DETAILED DESCRIPTION

Hereinafter, embodiments of inventive concepts will be described in detail with reference to the accompanying drawings. Like reference numerals are used for the same components in the drawings, and descriptions thereof are omitted.

Hereinafter, a photoresist composition and a method of manufacturing an integrated circuit device using the photoresist composition according to an embodiment will be described.

In some embodiments, the photoresist composition may be used for forming a pattern or fabricating an integrated circuit device. For example, the photoresist composition may be used in a patterning process for manufacturing an integrated circuit device. The photoresist composition may be an extreme ultraviolet (EUV) photoresist composition. Extreme ultraviolet rays may denote ultraviolet rays having a wavelength in a range of about 13.0 nm to about 13.9 nm, more specifically, a wavelength in a range of about 13.4 nm to about 13.6 nm. Extreme ultraviolet rays may refer to light having energy in a range of about 90 eV to about 95 eV. The photoresist composition may be a chemically amplified resists (CAR) type photoresist composition.

In some embodiments, the photoresist composition may include a chemically amplified polymer, a photo acid generator (PAG), and a photo-decomposable quencher (PDQ).

In the photoresist composition according to an embodiment, the chemically amplified polymer may include a polymer including a repeating unit in which the solubility of a developing solution may be changed by an action of an acid. The chemically amplified polymer may be a block copolymer or a random copolymer. In example embodiments, the chemically amplified polymer may include a positive photoresist. The positive photoresist may be a resist for KrF excimer laser (248 nm), a resist for ArF excimer laser (193 nm), a resist for F2 excimer laser (157 nm), or a resist for extreme ultraviolet (EUV) (13.5 nm).

In example embodiments, the chemically amplified polymer may include a repeating unit that is decomposed by an acid and increases solubility for an alkaline developer. In other embodiments, the chemically amplified polymer may include a repeating unit that is decomposed by an action of an acid to generate phenolic acid or BrØnsted acid corresponding to the phenolic acid. For example, the chemically amplified polymer may include a first repeating unit derived from hydroxystyrene or a hydroxystyrene derivative. The hydroxystyrene derivative may include hydroxystyrene in which the hydrogen atom at an a position is substituted with an alkyl group having 1 to 5 carbon atoms or substituted with a halogenated alkyl group having 1 to 5 carbon atoms, and derivatives thereof. For example, the first repeating unit may be derived from 3-hydroxystyrene, 4-hydroxystyrene, 5-hydroxy-2-vinylnaphthalene, or 6-hydroxy-2-vinylnaphthalene.

In other embodiments, the chemically amplified polymer may have a structure in which the first repeating unit derived from hydroxystyrene or a hydroxystyrene derivative and at least one second repeating unit having an acid-labile group are copolymerized. The at least one second repeating unit may include a (meth)acrylate-based polymer. For example, the at least one second repeating unit may include a binary or ternary copolymer of repeating units of polymethylmethacrylate (PMMA), poly(t-butylmethacrylate), poly(methacrylic acid), poly(norbornylmethacrylate), or (meth)acrylate-based polymers.

In another embodiment, the chemically amplified polymer may include a blend of a first polymer having the first repeating unit and a second polymer having the at least one second repeating unit.

The acid-decomposable group that may be included in the at least one second repeating unit may include a tert-butoxycarbonyl (t-BOC) group, an isonorbornyl group, a 2-methyl-2-adamantyl group, a 2-ethyl-2-adamantyl group, a 3-tetrahydrofuranyl group, a 3-oxocyclohexyl group, a γ-butyllactone-3-yl group, a mevalo mavaloniclactone group, a γ-butyrolactone-2-yl group, a 3-methyl-γ-butyrolactone-3-yl group, a 2-tetrahydropyranyl group, a 2-tetrahydrofuranyl group, a 2,3-propylenecarbonate-1-yl group, a 1-methoxyethyl) group, a 1-ethoxyethyl group, a 1-(2-methoxyethoxy) ethyl group, a 1-(2-acetoxyethoxy) ethyl group, a t-butoxycarbonylmethyl group, a methoxymethyl group, an ethoxymethyl group, a trimethoxysilyl group, or a triethoxysilyl group, but is not limited thereto.

In other embodiments, the chemically amplified polymer may further include at least one of a third repeating unit having an acrylate derivative substituent including a hydroxyl group (—OH) and a fourth repeating unit having a protecting group substituted with fluorine.

The chemically amplified polymer may have an average molecular weight in a range of about 1,000 to about 500,000. The content of the chemically amplified polymer in a photoresist composition may be in a range about 1 wt % to about 25 wt % based on the total weight of the photoresist composition.

In the photoresist composition according to an embodiment, the photoacid generator may generate acid when exposed to light. For example, the photoacid generator may generate acid when exposed to extreme ultraviolet (EUV).

The photoacid generator may include, for example, triarylsulfonium salts, diaryliodonium salts, sulfonates, or mixtures thereof. For example, the photoacid generator may include triphenylsulfonium triflate, triphenylsulfonium antimonate, triphenylsulfonium difluoroalkyl sulfonate, diphenylsulfonium Iodonium triflate, diphenyliodonium antimonate, methoxydiphenyliodonium triflate, di-t-butyldiphenyliodonium triflate, 2,6-dinitrobenzyl sulfonates, pyrogallol tris(alkylsulfonates), N-hydroxysuccinimide triflate, norbornene-dicarboximide-triflate, triphenylsulfonium nonaflate, diphenyliodonium nonaflate, methoxydiphenyliodonium nonaflate, di-t-butyldiphenyliodonium nonaflate, N-hydroxysuccinimide nonaflate, norbornene-dicarboximide-nonaflate, triphenylsulfonium perfluorobutanesulfonate, triphenylsulfonium perfluorooctanesulfonate (PFOS), diphenyliodonium PFOS, methoxydiphenyliodonium PFOS, di-t-butyldiphenyliodonium triflate, N N-hydroxysuccinimide PFOS, norbornene-dicarboximide PFOS, or a mixture thereof.

In the photoresist composition according to embodiments, the photoacid generator may be included in an amount of about 0.1% by weight to about 5.0% by weight based on the total weight of the chemically amplified polymer, but is not limited thereto.

The photo-decomposable quencher may include a compound capable of trapping acid in the non-exposed area when the acid generated from the photoacid generator included in the photoresist composition according to embodiments diffuses into the non-exposed area of the photoresist film. Because the photoresist composition for extreme ultraviolet rays according to embodiments includes the photo-decomposable quencher, the acid diffusion rate may be suppressed.

In a photolithography process using the photoresist composition according to an embodiment, when a partial area of a photoresist film obtained from the photoresist composition is exposed, acid is generated from the photoacid generator in the exposed area of the photoresist film, and an acid-labile group is deprotected from the chemically amplified polymer constituting the photoresist film. In the chemically amplified polymer constituting the resist film, the acid-labile group is deprotected and changed to a state that can be easily dissolved in an alkaline developer. In the unexposed area of the photoresist film, the photo-decomposable quencher remains as a base without being decomposed and may serve to neutralize acids undesirably present in the unexposed area. Accordingly, a difference in acidity between the exposed and unexposed areas of the photoresist layer may be increased and/or maximized, and thus a difference in solubility in a developer solution between the exposed and unexposed areas may be increased. In addition, by manufacturing an integrated circuit device using the photoresist composition according to an embodiment, it is possible to improve the dimensional accuracy of a pattern for the integrated circuit device, and improve the productivity of the manufacturing process of the integrated circuit device.

According to an embodiment of the present disclosure, the photo-decomposable quencher generates a neutral substance by exposure, and may act as a base neutralizing an acid before exposure. The photo-decomposable quencher of the present disclosure may be represented by Chemical Formula 1 to Chemical Formula 2 below.

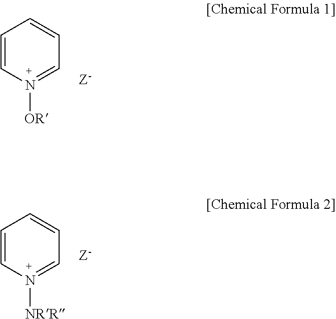

In Chemical Formulae 1 and 2, R′ may be a methyl group and R″ may be a tosyl group. Z⁻ may be a counter ion. A photo-decomposable quencher may include a carboxylate group or a sulfonate group. For example, Z⁻ may be an anion of a C1-C20 carboxylic acid. The carboxylic acid may be, for example, formic acid, acetic acid, propionic acid, tartaric acid, succinic acid, cyclohexylcarboxylic acid, benzoic acid, or salicylic acid, but is not limited thereto. Z⁻ may include a material represented by the following Chemical Formula Z.

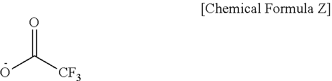

According to one embodiment, the photoresist composition includes a photo-decomposable quencher including a pyridinium-based material, and thus, even if the photo-decomposable quencher is decomposed in the non-exposed area, acid is not generated. Therefore, there is an effect of limiting and/or preventing deterioration of the non-exposed area due to acid generation. Specifically, the photo-decomposable quencher according to an embodiment may generate a neutral substance such as alcohol or sulfonamide by exposure to light. Therefore, because acid is not generated by exposure, there is an effect of limiting and/or preventing deterioration of the unexposed area due to acid generation even if the photo-decomposable quencher is decomposed in the unexposed area.

The photo-decomposable quencher according to an embodiment may be represented by Chemical Formula 1-1 to Chemical Formula 2-1 below. Various functional groups may be bound to the pyridine portion of the photo-decomposable quencher.

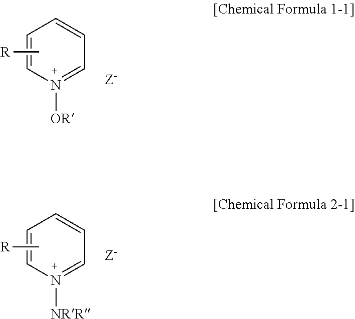

In this case, R may be hydrogen, a halogen element, or a substituted or unsubstituted alkyl group; R′ may be a methyl group; and R″ may be a tosyl group. In this case, the alkyl group may be a methyl group, an ethyl group, an n-propyl group, an isopropyl group, an n-butyl group, or a t-butyl group, but is not limited thereto. The alkyl group may be, for example, a fluoromethyl group, a difluoromethyl group, a trifluoromethyl group, a 2,2,2-trifluoroethyl group, a pentafluoroethyl group, a heptafluoropropyl group, a perfluorobutyl group, a perfluoropentyl group, a perfluorohexyl group, a perfluoroheptyl group, a perfluorooctyl group, a perfluorononyl group, or a perfluorodecyl group, but is not limited thereto. The methyl group may be, for example, a fluoromethyl group, a difluoromethyl group , or a trifluoromethyl group, but is not limited thereto.

The photo-decomposable quencher according to an embodiment may be represented by Chemical Formula 3 to Chemical Formula 3-1 below. The photo-decomposable quencher may include a zwitterion. For example, the photo-decomposable quencher may include a pyridinium ylide molecule in which a cation and an anion are present in one molecule. In this case, the pyrinidium ylide may be N-pyridinium ylide, but is not limited thereto.

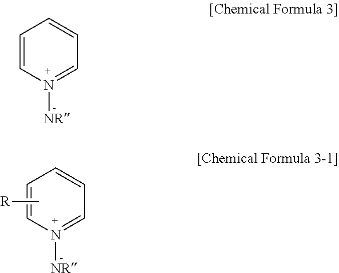

The photo-decomposable quencher represented by Chemical Formulas 1 to 3-1 may have a smaller molecular weight and hydrophilic properties compared to a photo-decomposable quencher including sulfonium or iodonium according to Comparative Example.

Because the photo-decomposable quencher according to an embodiment has a smaller molecular weight than the photo-decomposable quencher according to Comparative Example, the volume exclusion effect may be improved. For example, the photo-decomposable quencher according to Chemical Formula 1 may be 110.1 g/mol, the photo-decomposable quencher according to Chemical Formula 2 may be 263.3 g/mol, and the photo-decomposable quencher according to Chemical Formula 3 may be 248.3 g/mol. Accordingly, there is an effect of limiting and/or preventing deterioration of the unexposed portion in a narrow pitch.

Because the photo-decomposable quencher according to an embodiment has a hydrophilic property, solubility in a photoresist developer may be improved. For example, because the photo-decomposable quencher according to Chemical Formulas 1 to 3-1 has a low molecular weight and has a hydrophilic property, the solubility of TMAH after exposure may be increased compared to the photo-decomposable quencher according to Comparative Example.

In the photoresist composition according to an embodiment, the photo-decomposable quencher may be included in an amount in a range of about 0.01% to about 25.0% by weight based on the total weight of the chemically amplified polymer, but is not limited thereto.

In the photoresist composition according to an embodiment, the photo-decomposable quencher of Chemical Formula 1 may be synthesized according to Reaction Formula 1 below.

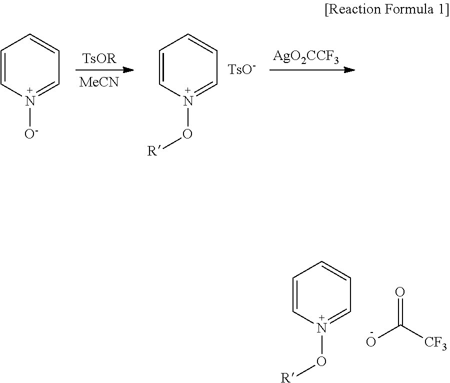

Referring to Reaction Formula 1, Chemical Formula 1 may be synthesized by reacting pyridinium oxide with tosyl ether (TsOR) and methylcyano (MeCN). In this case, R′ may be a methyl group.

In the photoresist composition according to an embodiment, the photo-decomposable quencher of Chemical Formula 2 may be synthesized according to Reaction Formula 2 below.

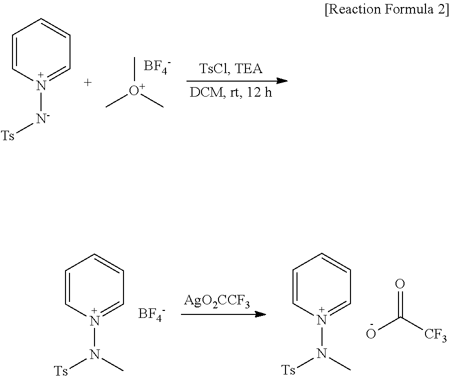

Referring to Reaction Formula 2, Chemical Formula 2 may be synthesized by reacting N-pyridinium ylide with dichloromethane (DCM), tosylchloride (TsCI) and triethylamine (TEA) at room temperature (rt: room temperature) for 12 hours.

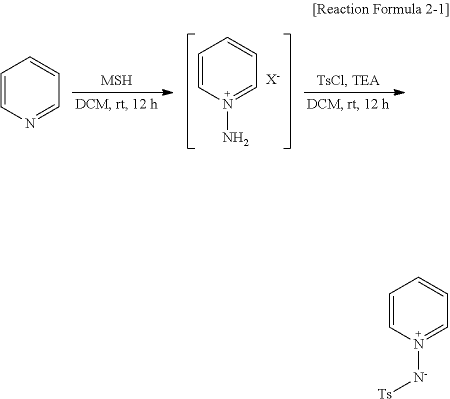

Referring to Reaction Formula 2-1, Chemical Formula 2-1 may be synthesized by reacting pyridine is reacted with ortho(methylsulfonyl)hydroxylamine (MSH) and dichloromethane (DCM) at room temperature for 12 hours. In this case, Chemical Formula 2-1 may be N-pyridinium ylide used in Reaction Formula 2 above.

In the photoresist composition according to an embodiment, the solvent may include an organic solvent. In some embodiments, the solvent may include at least one of ether, alcohol, glycol ether, aromatic hydrocarbon compound, ketone, and ester. For example, the solvent may be selected from ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monomethyl ether acetate, propylene glycol monoethyl ether, propylene glycol monoethyl ether acetate, propylene glycol propyl ether acetate, propylene glycol monobutyl ether, propylene glycol monobutyl ether acetate, toluene, xylene, methyl ethyl Ketone, cyclopentanone, cyclohexanone, ethyl 2-hydroxypropionate, ethyl 2-hydroxy-2-methyl ethyl propionate, ethyl ethoxyacetate, ethyl hydroxyacetate, methyl 2-hydroxy-3-methyl butanoate, methyl 3-methoxymethylpropionate, ethyl 3-methyl ethyl oxypropionate, ethyl 3-ethoxyethylpropionate, methyl 3-ethoxymethylpropionate, methyl pyruvate, ethyl pyruvate, ethyl acetate, butyl acetate, ethyl lactoate, butyl lactoate, etc . . . These solvents may be used alone or in combination of at least two.

In some embodiments, the amount of the solvent in the photoresist composition may be adjusted so that the solid content in the photoresist composition is in a range of about 0.5 wt % to about 20 wt %.

In example embodiments, the photoresist composition according to embodiments may further include a surfactant.

The surfactant may be selected from fluoroalkylbenzenesulfonate, fluoroalkylcarboxylate, fluoroalkylpolyoxyethylene ether, fluoroalkylammonium iodide, fluoroalkylbetaine, fluoroalkylsulfonate, diglycerin tetrakis (fluoroalkyl polyoxyethylene ether), fluoroalkyltrimethylammonium salt, fluoroalkylaminosulfonate, polyoxyethylene nonylphenyl ether, polyoxyethylene octylphenyl ether, polyoxyethylene alkyl ether, polyoxyethylene lauryl ether, poly Oxyethylene oleyl ether, polyoxyethylene tridecyl ether, polyoxyethylene cetyl ether, polyoxyethylene stearyl ether, polyoxyethylene laurate, polyoxyethylene oleate, polyoxyethylene stearate, polyoxyethylene laurylamine , sorbitan laurate, sorbitan palmitate, sorbitan stearate, sorbitan oleate, sorbitan fatty acid ester, polyoxyethylene sorbitan laurate, polyoxyethylene sorbitan palmitate, polyoxyethylene sorbitan stearate, It may be selected from polyoxyethylene sorbitan oleate, polyoxyethylene naphthyl ether, alkylbenzenesulfonic acid salts, and alkyldiphenyl ether disulfonic acid salts, but is not limited thereto.

The surfactant may be included in an amount in a range of about 0.001% by weight to about 0.1% by weight based on the total weight of the chemically amplified polymer, but is not limited thereto.

In example embodiments, the photoresist composition according to embodiments may further include a pigment, a preservative, an adhesion promoter, a coating aid, a plasticizer, a surface modifying agent, and/or a dissolution inhibitor. Next, synthetic examples of the photodegradable compound according to example embodiments of inventive concepts will be described with specific examples. The following examples are merely non-limiting examples to aid understanding of the synthesis process of the photodegradable compound according to example embodiments of inventive concepts, and the scope of inventive concepts is not limited to the following examples.

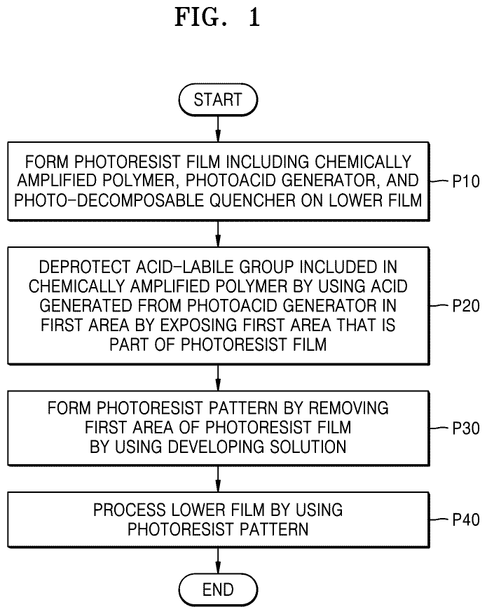

FIG. 1 is a flowchart illustrating a method of manufacturing an integrated circuit device according to an embodiment.

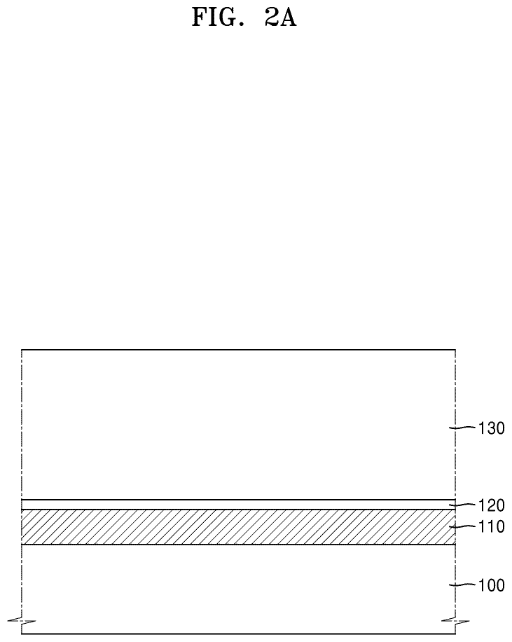

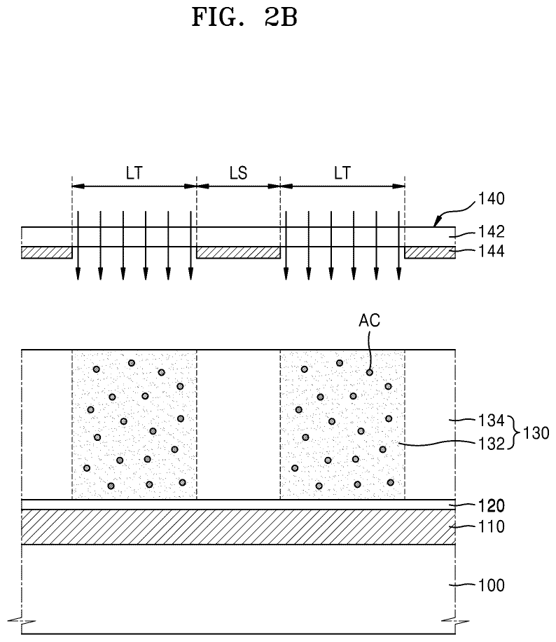

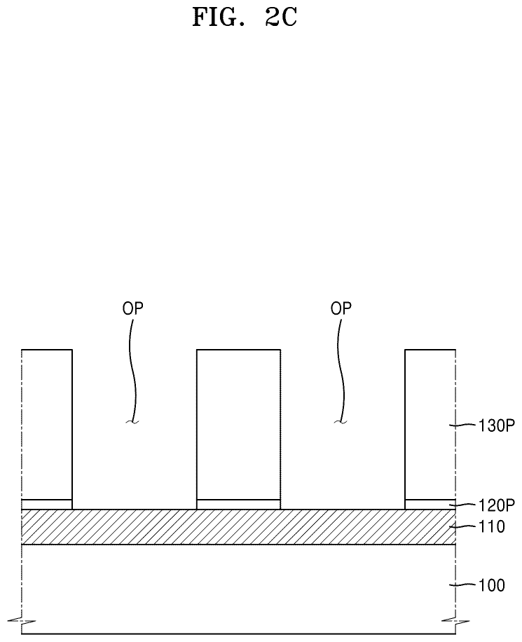

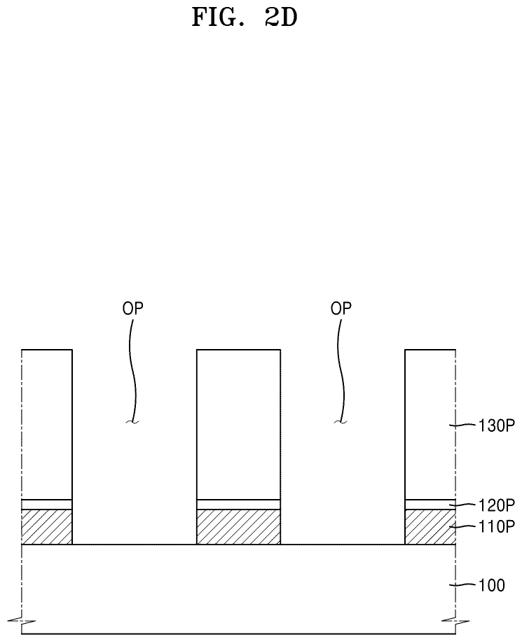

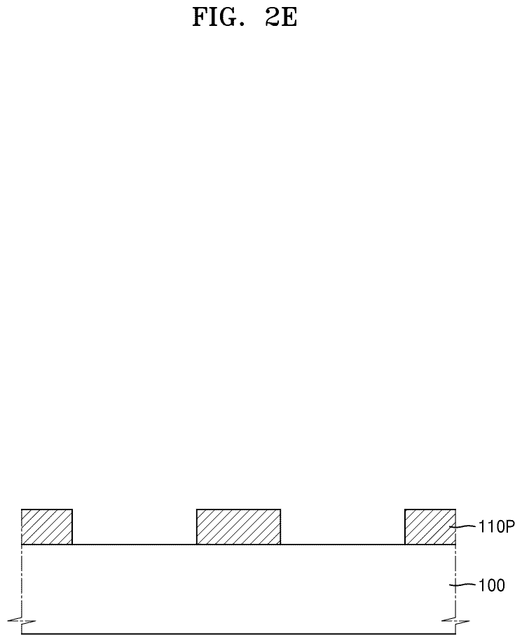

FIGS. 2A to 2E are cross-sectional views sequentially illustrating a method of manufacturing an integrated circuit device in sequence, according to an embodiment.

Referring to FIGS. 1 and 2A, in process P10 of FIG. 1, a photoresist film 130 may be formed on a lower film. The lower film may include a substrate 100 and a feature layer 110 formed on the substrate 100.

The substrate 100 may include a semiconductor substrate. For example, the substrate 100 may include a semiconductor material such as Si or Ge or a compound semiconductor material such as SiGe, SiC, GaAs, InAs, or InP.

The feature layer 110 may be an insulating layer, a conductive layer, or a semiconductor layer. For example, the feature layer 110 may include a metal, alloy, metal carbide, metal nitride, metal oxynitride, metal oxycarbide, semiconductor, polysilicon, oxide, nitride, oxynitride, or combinations thereof, but is not limited thereto.

In example embodiments, as illustrated in FIG. 2A, a developable bottom anti-reflective coating (DBARC) film 120 may be formed before forming the photoresist film 130 on the feature layer 110. In this case, the photoresist film 130 may be formed on the DBARC film 120. The DBARC film 120 may control irregular reflection of light from a light source used in an exposure process for manufacturing an integrated circuit device or absorb reflected light from the feature layer 110 thereunder. In example embodiments, the DBARC film 120 may include an organic anti-reflective coating (ARC) material for a KrF excimer laser, an ArF excimer laser, an EUV laser, or any other light source. In example embodiments, the DBARC film 120 may include an organic component having a light absorbing structure. The light absorption structure may be, for example, a hydrocarbon compound having one or more benzene rings or a structure in which benzene rings are fused. The DBARC film 120 may be formed to a thickness in a range of about 20 nm to about 100 nm, but is not limited thereto. In example embodiments, the DBARC film 120 may be omitted.

To form the photoresist film 130, a photoresist composition including a chemically amplified polymer, a photoacid generator, a photo-decomposable quencher, and a solvent may be used. The photo-decomposable quencher generates a neutral substance by exposure to light and may act as a base neutralizing an acid before the exposure. For example, the photo-decomposable quencher may be represented by Chemical Formula 1 to Chemical Formula 3-1, and a more detailed description of the photo-decomposable quencher is as described above.

In order to form the photoresist film 130, a photoresist composition according to an embodiment may be coated on the DBARC film 120 and then the coating is heat treated. The coating may be performed by a spin coating method, a spray coating method, or a deep coating method. The process of heat-treating the photoresist composition may be performed at a temperature in a range of about 80° C. to about 300°° C. for about 10 seconds to about 100 seconds, but is not limited thereto. The thickness of the photoresist film 130 may be several tens to hundreds of times the thickness of the DBARC film 120. The photoresist film 130 may be formed to a thickness in a range of about 100 nm to about 6 μm, but is not limited thereto.

Referring to FIGS. 1 and 2B, in process P20, a first area 132, which is a part of the photoresist film 130, is exposed to generate acid AC from the photoacid generator from the first area of the photoresist film 130 and an acid-labile group included in the chemically amplified polymer may be deprotected.

When the first area 132 of the photoresist film 130 is exposed, carboxylate anion (—COO—), which a hydrophilic functional group having a relatively bulky structure, is formed from the photo-decomposable quencher in the first area 132, and as a result, solubility in the developing solution may be increased. Therefore, when the photoresist film 130 exposed to the first area 132 is developed in a subsequent process, a difference in solubility in the developing solution between the exposed area and the unexposed area may increase, thereby increasing contrast.

In example embodiments, to expose the first area 132 of the photoresist film 130, a photomask 140 having a plurality of light shielding areas (LS) and a plurality of light transmitting areas (LT) is aligned at a desired and/or alternatively predetermined position on the photoresist film 130, and the first area 132 of the photoresist film 130 may be exposed through the plurality of light-transmitting areas LT of the photomask 140. To expose the first area 132 of the photoresist film 130, a KrF excimer laser (248 nm), an ArF excimer laser (193 nm), an F2 excimer laser (157 nm), or an EUV laser (13.5 nm) may be used.

The photomask 140 may include a transparent substrate 142 and a plurality of light shielding patterns 144 formed in a plurality of light shielding areas LS on the transparent substrate 142. The transparent substrate 142 may include quartz. The plurality of light shielding patterns 144 may be made of chromium (Cr). A plurality of light transmission areas LT may be defined by a plurality of light shielding patterns 144.

In example embodiments, an annealing process may be performed to diffuse a plurality of acids AC generated in the first area 132 of the photoresist film 130 . For example, in process P20 of FIG. 1, a resultant product obtained after exposing the first area 132 of the photoresist film 130 is annealed at a temperature in a range of about 50° C. to about 150° C. so that at least a portion of the plurality of acids AC is diffused in the first area 132 and, as a result, is relatively uniformly distributed in the first area 132. The annealing may be performed for in a range of about 10 seconds to about 100 seconds. In one example, the annealing process may be performed for about 60 seconds at a temperature of about 100° C.

In other embodiments, a separate annealing process may not be performed to diffuse a plurality of acids AC in the first area 132 of the photoresist film 130. In this case, during the exposure of the first area 132 of the photoresist film 130 in process P20 of FIG. 1, a plurality of acids AC may be diffused in the first area 132 of the photoresist film 130 without a separate annealing process.

As a result of the diffusion of a plurality of acids AC in the first area 132 of the photoresist film 130, the acid-labile group of the chemically amplified polymer constituting the photoresist film 130 in the first area 132 is deprotected, and the first area 132 of the photoresist film 130 may be changed into a state that may be easily dissolved in an alkaline developer.

When the photoresist film 130 includes a photo-decomposable quencher, the photo-decomposable quencher included in the photoresist film 130 in the second area 134, which is an unexposed area, may act as a quenching base to neutralize acids that have undesirably diffused into the second area 134 from the first area 132. In example embodiments, the photo-decomposable quencher included in the photoresist film 130 in the second area 134 may perform a neutralizing role of acids that have undesirably diffused from the first area 132 to the second area 134.

Referring to FIGS. 1 and 2C, in process P30, the first area 132 of the photoresist film 130 may be removed by developing the photoresist film 130 using a developing solution. As a result, a photoresist pattern 130P consisting of (or including) the unexposed second area 134 of the photoresist layer 130 may be formed.

The photoresist pattern 130P may include a plurality of openings OP. After the photoresist pattern 130P is formed, the DBARC pattern 120P may be formed by removing portions of the DBARC film 120 exposed through the plurality of openings OP.

In example embodiments, an alkaline developer may be used to develop the photoresist film 130. The alkaline developer may include a tetramethylammonium hydroxide (TMAH) solution with 2.38% by weight.

In a resultant product of FIG. 2B, because the chemically amplified polymer is deprotected by a plurality of acids AC in the first area 132 of the photoresist film 130, while the photoresist film 130 is developed with the developer, the solubility of the first area 132 with respect to the developer is improved, and thus, the first area 132 may be cleanly removed. Therefore, after the development of the photoresist film 130, residual defects such as a bridge phenomenon and a footing phenomenon may not occur, and a vertical sidewall profile may be obtained in the photoresist pattern 130P. In this way, because the profile of the photoresist pattern 130P is improved, when the feature layer 110 is processed using the photoresist pattern 130P, a critical dimension of an intended processing area in the feature layer 110 may be precisely controlled.

Referring to FIGS. 1 and 2D, in process P40, a lower film may be processed using the photoresist pattern 130P in a resultant product of FIG. 2C.

In order to process the lower layer, various processes may be performed, for example, a process of etching the feature layer 110 exposed through the opening OP of the photoresist pattern 130P, a process of implanting impurity ions into the feature layer 110, a process of forming an additional film on the feature layer 110 through the opening OP, and a process of deforming a portion of the feature layer 110 through the opening OP. FIG. 2D illustrates a case in which the feature pattern 110P is formed by etching the feature layer 110 exposed through the opening OP as an example process of processing the lower film. The photoresist pattern 130P may be used as a mask when the exposed portion of the feature layer 110 is etched.

In other embodiments, the process of forming the feature layer 110 may be omitted from the process described with reference to FIG. 2A, and in this case, instead of the process P40 of FIG. 1 and the process described with reference to FIG. 2D, the substrate 100 may be processed using the pattern 130P. For example, using the photoresist pattern 130P, various processes, such as a process of etching a portion of the substrate 100, a process of implanting impurity ions into a portion of the substrate 100, a process of forming an additional film on the substrate 100 through the opening OP, and a process of deforming a part of the substrate 100 through the opening OP may be performed.

Referring to FIG. 2E, in a resultant product of FIG. 2D, the photoresist pattern 130P and the DBARC pattern 120P remaining on the feature pattern 110P may be removed. An ashing and strip process may be used to remove the photoresist pattern 130P and the DBARC pattern 120P.

According to the method of manufacturing an integrated circuit device according to an embodiment described with reference to FIGS. 1 and 2A to 2E, the difference in solubility in a developer solution in the exposed area and the unexposed area of the photoresist film 130 obtained by using the photoresist composition according to an embodiment increases, and accordingly, line edge roughness (LER) and line width roughness (LWR) are reduced in the photoresist pattern 130P obtained from the photoresist film 130 to provide high pattern fidelity. Accordingly, when a subsequent process is performed with respect to the feature layer 110 and/or the substrate 100 using the photoresist pattern 130P, the dimensional accuracy of processing regions or patterns to be formed on the feature layer 110 and/or the substrate 100 may be precisely controlled, and as a result, dimensional accuracy may be improved. In addition, the critical dimension (CD) distribution of patterns to be implemented on the substrate 100 may be uniformly controlled, and productivity of a process for manufacturing an integrated circuit device may be improved.

As described above, example embodiments of inventive concepts have been disclosed in the drawings and specification. In the present specification, the example embodiments are described by using some specific terms, but the terms used are for the purpose of describing the technical scope of inventive concepts only and are not intended to be limiting of meanings or the technical scope described in the claims. Therefore, it will be understood by those skilled in the art that various changes in form and details may be made therein without departing from the spirit and scope of inventive concepts as defined by the appended claims. Accordingly, the scope of inventive concepts is defined not by the detailed description but by the appended claims.

While inventive concepts has been particularly shown and described with reference to embodiments thereof, it will be understood that various changes in form and details may be made therein without departing from the spirit and scope of the following claims.

What is claimed is:

1. A photoresist composition comprising:
a chemically amplified polymer;
a photoacid generator;
a photo-decomposable quencher including a pyridinium-based material that generates a neutral material by exposure and acts as a base to neutralize an acid before exposure; and
a solvent.

2. The photoresist composition of claim 1, wherein the photo-decomposable quencher is represented by one of Chemical Formulas 1 and 2 below: 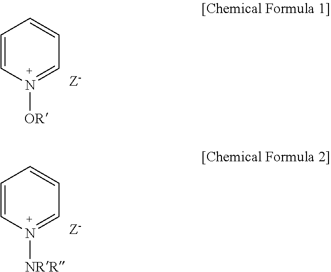
wherein, in Chemical Formulas 1 and 2,
Z⁻ is a counter ion,
R′ is a methyl group, and
R″ is a tosyl group.

3. The photoresist composition of claim 2, wherein Z⁻ is an anion of a C1 to C20 carboxylic acid.

4. The photoresist composition of claim 1, wherein the photo-decomposable quencher is represented by one of Chemical Formula 1-1 and Chemical Formula 2-1 below: 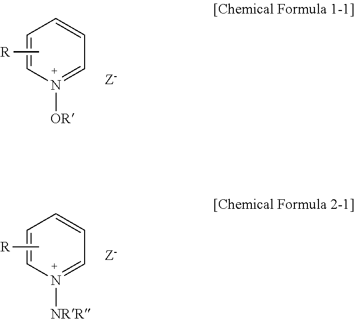
wherein, in Chemical Formula 1-1 and 2-1,
Z⁻ is a counter ion,
R is hydrogen, a halogen element, or a substituted or unsubstituted alkyl group,
R′is a methyl group, and
R″ is a tosyl group.

5. The photoresist composition of claim 4, wherein
R is a halogen element or a substituted or unsubstituted alkyl group.

6. The photoresist composition of claim 1, wherein the photo-decomposable quencher is represented by Chemical Formula 3 below: 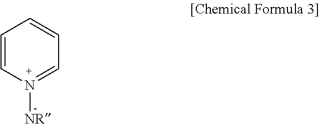
wherein, in Chemical Formula 3,
R″ is a tosyl group.

7. The photoresist composition of claim 1, wherein the photo-decomposable quencher is represented by [Chemical Formula 3-1] below: 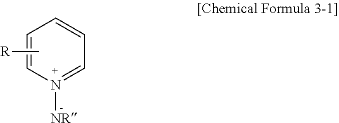
wherein, in Chemical Formula 3-1,
R is hydrogen, a halogen element, or a substituted or unsubstituted alkyl group, and
R″ is a tosyl group.

8. The photoresist composition of claim 7, wherein
R is a halogen element or a substituted or unsubstituted alkyl group.

9. The photoresist composition of claim 1, wherein
the photo-decomposable quencher has a weight of about 0.1% by weight to about 25% by weight, based on a total weight of the chemically amplified polymer.

10. A photo-decomposable quencher comprising:
a pyridinium-based material that generates a neutral material by exposure and acts as a base to neutralize an acid before exposure,
the pyridinium-based material being represented by one of Chemical Formulas 1, 1-1, 2, 2-1, 3, and 3-1 below, 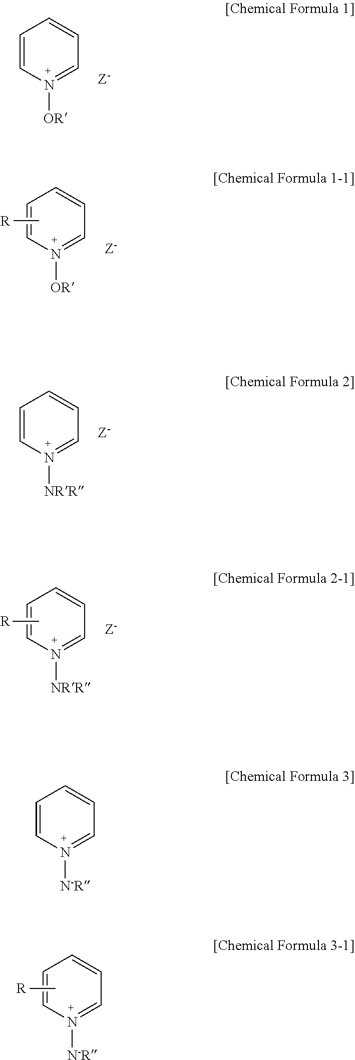
wherein, in Chemical Formulas 1, 1-1, 2, 2-1, 3, and 3-1,
Z⁻ is a counter ion,
R is hydrogen, a halogen element, or a substituted or unsubstituted alkyl group,
R′ is a methyl group, and
R″ is a tosyl group.

11. The photo-decomposable quencher of claim 10, wherein
the pyridinium-based material is represented by one of Chemical Formulas 1, 1-1, 2, and 2-1, and
Z⁻ is an anion of a C1 to C20 carboxylic acid.

12. The photo-decomposable quencher of claim 10, wherein
the photo-decomposable quencher is represented by one of Chemical Formulas 1-1, 2-1, and 3-1.

13. The photo-decomposable quencher of claim 12, wherein
R is a halogen element or a substituted or unsubstituted alkyl group.

14. A method of manufacturing an integrated circuit device, the method comprising:
forming a photoresist film on a lower film by using a photoresist composition,
the photoresist film including a chemically amplified polymer, a photoacid generator, and a photo-decomposable quencher,
the photo-decomposable quencher including a pyridinium-based material that generates a neutral material by exposure and acts as a base to neutralize an acid before exposure;
exposing a first area of the photoresist film to provide an exposed first area of the photoresist film,
the exposing the first area of the photoresist film generating an acid in the first area, the acid being derived from the photoacid generator;
deprotecting an acid-labile group included in the chemically amplified polymer using the acid in the exposed first area of the photoresist film;
forming a photoresist pattern by removing the exposed first area of the photoresist film using a developing solution, the photoresist pattern including an unexposed area of the photoresist film; and
processing the lower film using the photoresist pattern as a mask.

15. The method of claim 14, wherein the photo-decomposable quencher is represented by one of Chemical Formula 1 to Chemical Formula 3 below: 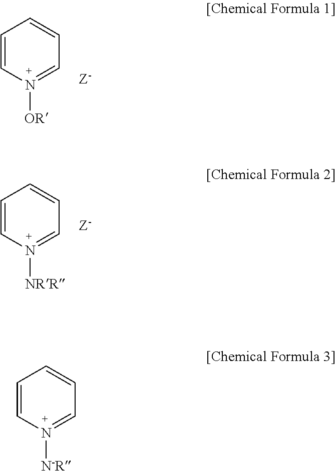
wherein, in Chemical Formulas 1, 2, and 3,
Z⁻ is a counter ion,
R′ is a methyl group, and
R″ is a tosyl group.

16. The method of claim 15, wherein Z⁻ is an anion of a C1 to C20 carboxylic acid.

17. The method of claim 15, wherein the photo-decomposable quencher is represented by one of Chemical Formula 1-1 to Chemical Formula 3-1 below: 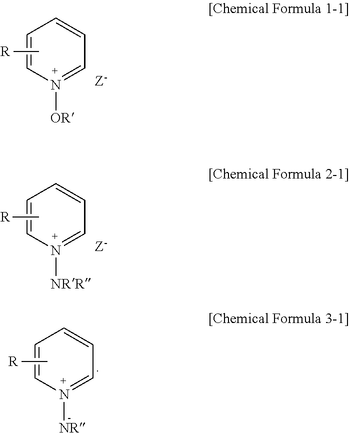
wherein, in Chemical Formulas 1-1, 1-2, and 1-3,
Z⁻ is a counter ion,
R is hydrogen, a halogen element, or a substituted or unsubstituted alkyl group,
R′ is a methyl group, and
R″ is a tosyl group.

18. The method of claim 17, wherein
R is a halogen element or a substituted or unsubstituted alkyl group,
R′is a methyl group, and
R″ is a tosyl group.

19. The method of claim 14, wherein, in the forming the photoresist film, a weight of the photo-decomposable quencher is in a range of about 0.1% by weight to 25% by weight, based on a total weight of the chemically amplified polymer.

20. The method of claim 14, wherein the exposing the first area of the photoresist film is performed with an extreme ultraviolet (EUV) laser.
